(19) United States
(12) Patent Application Publication
(10) Pub. No.: US 2018/0277598 A1
(43) Pub. Date: Sep. 27, 2018

(54) SEMICONDUCTOR DEVICE

(71) Applicant: TOSHIBA MEMORY CORPORATION, Tokyo (JP)

(72) Inventors: Minoru ODA, Yokkaichi Mie (JP); Akira YOTSUMOTO, Yokkaichi Mie (JP); Nobuyuki MOMO, Yokkaichi Mie (JP); Kotaro NODA, Yokkaichi Mie (JP)

(73) Assignee: TOSHIBA MEMORY CORPORATION, Tokyo (JP)

(21) Appl. No.: 15/705,219

(22) Filed: Sep. 14, 2017

(30) Foreign Application Priority Data
Mar. 27, 2017 (JP) 2017-061468

(51) Int. Cl. H01L 27/24; H01L 45/00

(52) U.S. Cl. CPC H01L 27/249; H01L 45/1683; H01L 45/085; H01L 27/2454

(57) ABSTRACT

A semiconductor device includes a semiconductor pillar and a control electrode. The semiconductor pillar extends in a first direction, and includes a first region, a second region and an intermediate region provided along the first direction. The intermediate region is positioned between the first region and the second region. The control electrode is disposed at a position so that the control electrode faces the intermediate region via an insulating film. The semiconductor pillar is provided so that a minimum width of the intermediate region in a second direction perpendicular to the first direction is narrower than a first width of the first region in the second direction and a second width of the second region in the second direction.

### CROSS-REFERENCE TO RELATED APPLICATIONS

This application is based upon and claims the benefit of priority from Japanese Patent Application No.2017-061468, filed on Mar. 27, 2017; the entire contents of which are incorporated herein by reference.

### FIELD

Embodiments generally relate to a semiconductor device.

### BACKGROUND

A vertical transistor is disposed between a lower-layer interconnection and a memory cell array located above the lower-layer interconnection, for example, in a storage device having memory cells disposed three-dimensionally. The vertical transistor includes a semiconductor pillar extending from the lower-layer interconnection toward an interconnection in the memory cell array, and a gate electrode disposed on the side surface of the semiconductor pillar. The vertical transistor controls, for example, a current flowing from the lower-layer interconnection to the memory cell array.

### BRIEF DESCRIPTION OF THE DRAWINGS

FIGS. 1A and 1B are schematic cross-sectional views showing a semiconductor device according to a first embodiment;

FIGS. 2A and 2B are graphic charts showing the characteristics of a transistor according to a comparative example;

FIG. 3 is another graphic chart showing the characteristics of transistors according to the comparative example;

FIGS. 4A to 6C are perspective views schematically showing a manufacturing process of the semiconductor device according to the first embodiment;

FIGS. 7A and 7B are schematic cross-sectional views showing a semiconductor device according to a second embodiment;

FIGS. 8A to 10B are perspective views schematically showing a manufacturing process of the semiconductor device according to the second embodiment;

FIGS. 11A and 11B are perspective views schematically showing a part of the manufacturing process of the semiconductor device according to the second embodiment;

FIGS. 12A to 12C are perspective views schematically showing a manufacturing process of the semiconductor device according to a third embodiment;

FIGS. 13A and 13B are schematic cross-sectional views showing a semiconductor device according to a fourth embodiment;

FIGS. 14A to 14C are perspective views schematically showing the manufacturing process of the semiconductor device according to the fourth embodiment;

FIG. 15 is a perspective view schematically showing a storage device according to a fifth embodiment; and

FIGS. 16A and 16B are perspective views schematically showing a manufacturing process of the storage device according to the fifth embodiment.

### DETAILED DESCRIPTION

According to one embodiment, a semiconductor device includes a semiconductor pillar and a control electrode. The semiconductor pillar extends in a first direction, and includes a first region, a second region and an intermediate region provided along the first direction. The intermediate region is positioned between the first region and the second region. The control electrode is disposed at a position so that the control electrode faces the intermediate region via an insulating film. The semiconductor pillar is provided so that a minimum width of the intermediate region in a second direction perpendicular to the first direction is narrower than a first width of the first region in the second direction and a second width of the second region in the second direction.

Embodiments will now be described with reference to the drawings. The same portions inside the drawings are marked with the same numerals; a detailed description is omitted as appropriate; and the different portions are described. The drawings are schematic or conceptual; and the relationships between the thicknesses and widths of portions, the proportions of sizes between portions, etc., are not necessarily the same as the actual values thereof. The dimensions and/or the proportions may be illustrated differently between the drawings, even in the case where the same portion is illustrated.

There are cases where the dispositions of the components are described with the directions of XYZ axes shown in the drawings. The X-axis, the Y-axis, and the Z-axis are orthogonal to each other. The directions of the X-axis, the Y-axis, and the Z-axis are described below as an X-direction, a Y-direction, and a Z-direction. There are cases where the Z-direction is described as upward and the direction opposite to the Z-direction is described as downward.

### First Embodiment

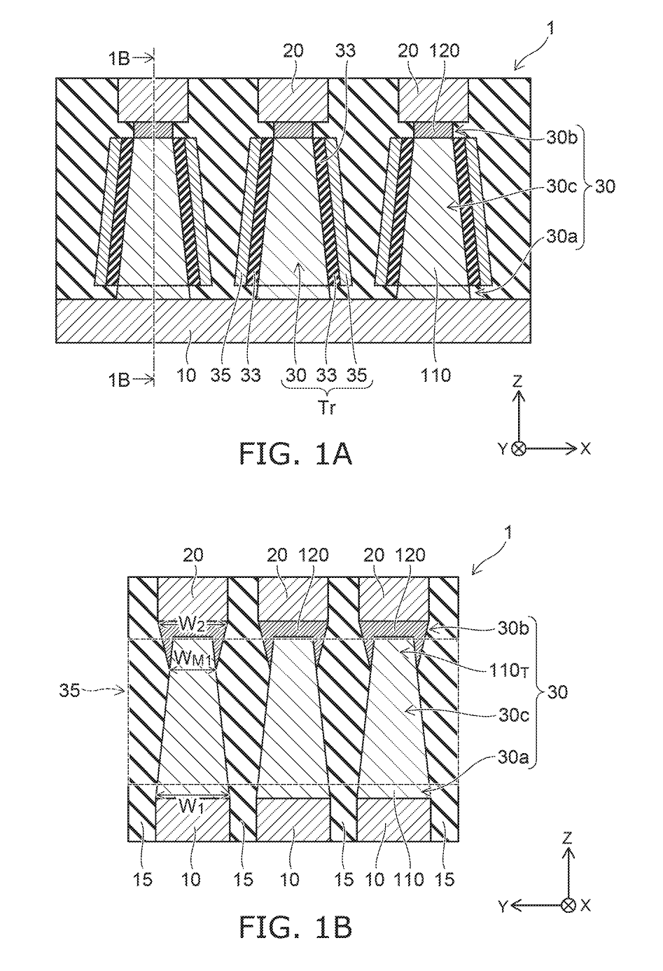

FIGS. 1A and 1B are schematic cross-sectional views showing a semiconductor device 1 according to a first embodiment. FIG. 1B is a cross-sectional view along a line 1B-1B shown in FIG. 1A. The semiconductor device 1 includes, for example, a plurality of transistors Tr, and performs ON/OFF control of currents flowing between the lower-layer interconnections (hereinafter referred to as interconnections 10) and the upper-layer interconnections (hereinafter referred to as interconnections 20).

As shown in FIG. 1A, the transistors Tr are disposed along the interconnections 10 extending, for example, in an X-direction. The transistors Tr each include a semiconductor pillar 30, a gate insulating film 33, and a gate electrode 35.

The semiconductor pillar 30 includes a semiconductor layer 110 provided on the interconnection 10, and a semiconductor layer 120 provided on the upper end of the semiconductor layer 110. Further, the semiconductor pillar 30 includes a first region 30a (e.g., a source region), a second region 30b (e.g., a drain region), and an intermediate region 30c (e.g., a channel region). The first region 30a is connected to the interconnection 10, and the second region 30b is connected to the interconnection 20. The intermediate region 30c is positioned between the first region 30a and the second region 30b. The gate electrode 35 is disposed at a position so that the gate electrode 35 faces the intermediate region 30c via the gate insulating film 33. The first region 30a and the second region 30b include impurities of same conductivity types, and include, for example, the impurities higher in concentration than the impurities of the same conductivity type included in the intermediate region 30c.

Alternatively, the intermediate region 30c can include impurities that are different in the conductivity type from the impurities included in the first region 30a and the second region 30b. For example, when the transistor Tr is an n-type MOSFET, the intermediate region 30c includes p-type impurities, and the first region 30a and the second region 30b include n-type impurities.

As shown in FIG. 1B, the semiconductor device 1 includes a plurality of interconnections 10, and the interconnections 10 are disposed so as to be arranged in a Y-direction via an insulating film 15. The semiconductor pillars 30 are provided on the respective interconnections 10. In other words, the semiconductor pillars 30 are disposed to form a grid pattern when viewed from above.

For example, as described later, the semiconductor layer 110 constituting the semiconductor pillar 30 is formed in a tapered shape with the width narrowing upward. Therefore, the semiconductor pillar 30 has a shape in which the width W₁ in the Y-direction of the first region 30a is wider than the minimum width W_{M1} in the Y-direction of the intermediate region 30c. Further, the second region 30b is provided so that the width W₂ in the Y-direction is wider than the minimum width W_{M1} of the intermediate region 30c. The width W₁ of the first region 30a is provided so as to be substantially equal to or wider than the width W₂ of the second region 30b. Further, the width W₂ of the second region 30b can also be provided so as to be wider than the width W₁ of the first region 30a.

In a X-Z cross-section of the semiconductor device 1, the width of the first region 30a in the X-direction becomes wider than the minimum width of the intermediate region 30c in the X-direction, and the width of the second region 30b in the X-direction is equal to or narrower than the minimum width of the intermediate region 30c in the X-direction.

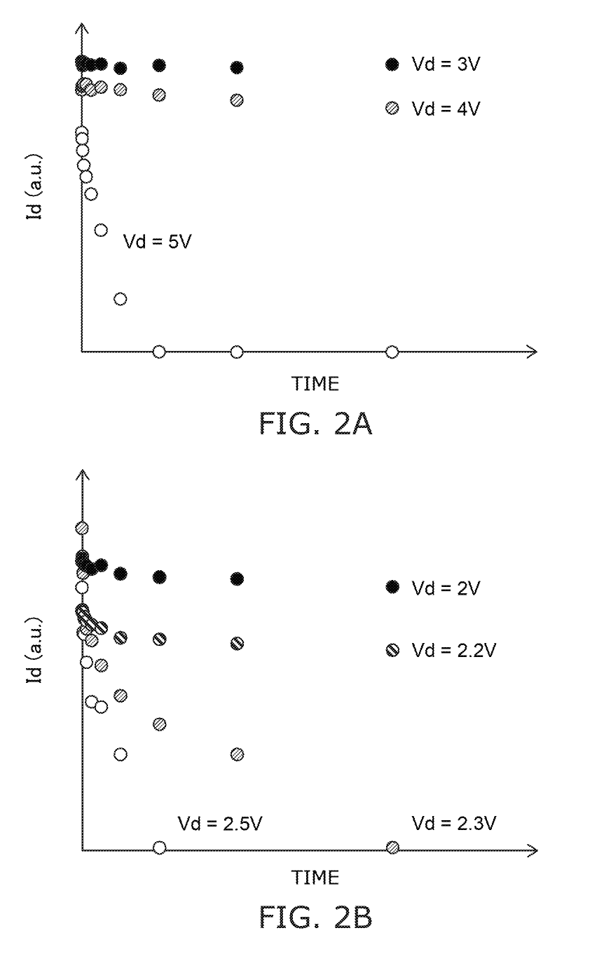

FIGS. 2A and 2B are graphic charts showing the characteristics of a transistor Tr according to a comparative example. The horizontal axis represents time, and the vertical axis represents the drain current Id. In the transistor Tr according to the comparative example, the semiconductor layer 120 is not provided (see FIGS. 1A and 1B). In other words, the semiconductor pillar 30 includes only the semiconductor layer 110 having the tapered shape with the widths in the X-direction and the Y-direction narrowing toward the direction from the first region 30a to the second region 30b.

FIG. 2A shows the drain current Id varying with time when the transistor Tr is biased so that the electrons move from the second region 30b toward the first region 30a. Further, FIG. 2A shows the temporal change of the current flowing between the first region 30a and the second region 30b (hereinafter referred to as the drain current Id) with respect to a voltage supplied between the first region 30a and the second region 30b (hereinafter referred to as a source-drain voltage Vd), i.e. Vd as a parameter.

As shown in FIG. 2A, the current value dramatically drops when setting Vd to 5 V compared to the case of setting Vd to 3 V or 4 V. For example, when the source-drain voltage Vd rises, the number of hot electrons are taken in the gate insulating film 33, and thus, the drain current exhibits a tendency to decrease with time. Further, when the semiconductor layer 110 is a polycrystalline silicon layer that includes grain boundaries, electrons are trapped at the grain boundaries around the first region 30a, resulting in the large variation of the threshold voltage, or forming crystalline defects in the vicinity of the second region 30b due to the hot electrons. Thereby, the drain current Id drastically decreases with time.

FIG. 2B shows the temporal change of the drain current Id when the transistor Tr is biased so that the electrons move from the first region 30a toward the second region 30b. Also in this case, the variation with time in the drain current Id is shown with the source-drain voltage Vd as a parameter. In the example shown in FIG. 2B, the reduction of the drain current Id occurs at a lower value of the source-drain voltage Vd than that of the example shown in FIG. 2A.

It is conceivable that such a difference between the characteristics shown in FIG. 2A and the characteristics shown in FIG. 2B is due to the shape of the semiconductor pillar 30. Specifically, the semiconductor pillar 30 in the comparative example has a tapered shape in which the second region 30b is narrower in width than the first region 30a. In other words, the characteristics shown in FIG. 2B shows the fact that the reduction of the drain current Id becomes more significant when the bias is applied so that the electrons move from the first region 30a to the second region 30b narrower in width.

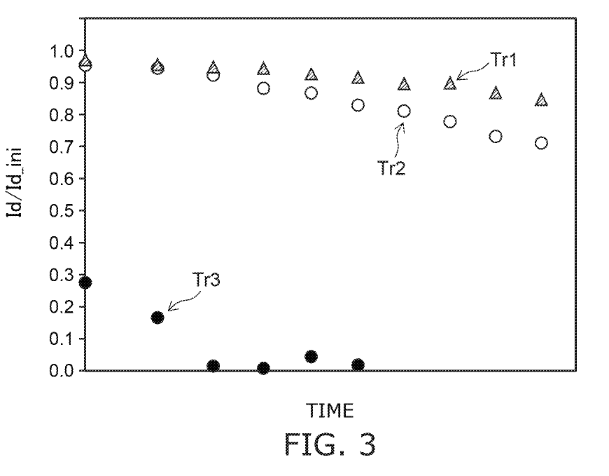

FIG. 3 is another graphic chart showing the characteristics of transistors Tr₁, Tr₂ and Tr₃ according to the comparative example. The horizontal axis represents time, and the vertical axis represents the drain current Id normalized by an initial value (Id_ini) of each transistor. The transistors Tr are different from each other in the widths of the semiconductor pillar 30 in the X-direction and the Y-direction. For example, the semiconductor pillar 30 of the transistor Tr₁ is wider than the semiconductor pillar 30 of the transistor Tr₂ in widths of the X-direction and the Y-direction, and the semiconductor pillar 30 of the transistor Tr₂ is wider than the semiconductor pillar 30 of the transistor Tr₃ in widths of the X-direction and the Y-direction.

As shown in FIG. 3, the decreasing rate of the drain current Id is the highest for the transistor Tr₃ which has the smallest width of the semiconductor pillar 30, and the decreasing rate of the drain current Id becomes smaller as the width of the semiconductor pillar 30 widens. Thus, it is found that suppressing the reduction of the drain current Id can be achieved by widening the widths in the X-direction and the Y-direction of the semiconductor pillar 30. In the semiconductor device 1 according to the embodiment, the reduction of the drain current Id is suppressed by making the width W₁ of the first region 30a and the width W₂ of the second region 30b in the Y-direction wider than the width W_{M1} in the Y-direction of the intermediate region 30c, thereby improving the reliability of the semiconductor device 1.

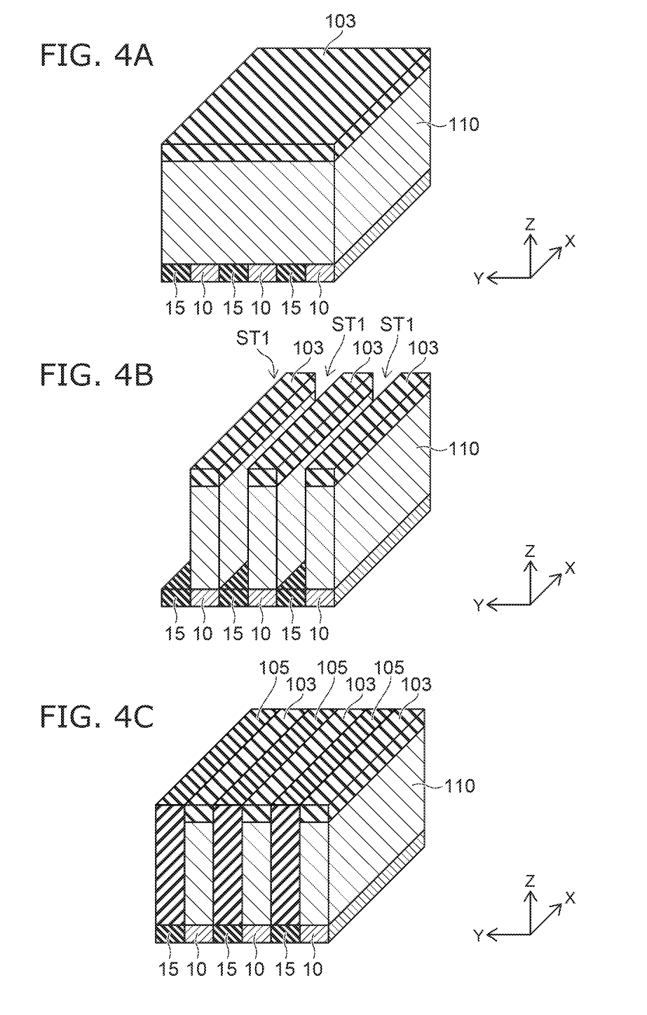

Then, a method of manufacturing the semiconductor device 1 according to the first embodiment will be described with reference to FIGS. 4A to 6C. FIGS. 4A to 6C are perspective views schematically showing the manufacturing process of the semiconductor device 1.

FIG. 4A is a perspective view showing a mask layer 103 and the semiconductor layer 110 formed on the interconnections 10 arranged in the Y-direction. It should be noted that the semiconductor layer 110 shown in FIGS. 1A and B corresponds to parts of the semiconductor layer 110 in FIG. 4A.

The interconnections 10 extend in the X-direction, and the insulating films 15 are formed between the interconnections 10 arranged in the Y-direction. The interconnections 10 are, for example, metal layers including tungsten (W) and titanium nitride (TiN). The insulating films 15 are, for example, silicon oxide films.

The semiconductor layer 110 is, for example, a polycrystalline silicon layer, and is deposited on the interconnections 10 and the insulating films 15 by a CVD process (a Chemical Vapor Deposition process). Alternatively, the semiconductor layer 110 may be a polycrystalline silicon-germanium layer, a polycrystalline germanium layer, or a compound semiconductor layer such as a polycrystalline indium-gallium-arsenide layer. The mask layer 103 is, for example, a silicon nitride layer deposited by a CVD process.

It should be noted that the impurities are doped to the upper part of the semiconductor layer 110, for example, during the deposition process thereof, or the impurities are introduced by ion implantation. Moreover, the impurities are doped to the lower part of the semiconductor layer 110 during the deposition process thereof. Thus, the semiconductor layer 110 is formed so as to include the higher impurity concentration in the upper part and the lower part than in the intermediate region between the upper part and the lower part.

As shown in FIG. 4B, slits ST1 are formed for dividing the semiconductor layer 110 into a plurality of parts. The slits ST1 are formed by selectively removing the semiconductor layer 110 by, for example, an anisotropic RIE (Reactive Ion Etching) process after the mask layer 103 is formed into a predetermined pattern by photolithography. The slits ST1 are formed so as to extend in the X-direction and have a depth from the upper surface of the semiconductor layer 110 to the insulating films 15.

As shown in FIG. 4C, insulating films 105 are formed in the slits ST1. The insulating films 105 are, for example, silicon oxide films, and are formed so as to fill the slits ST1.

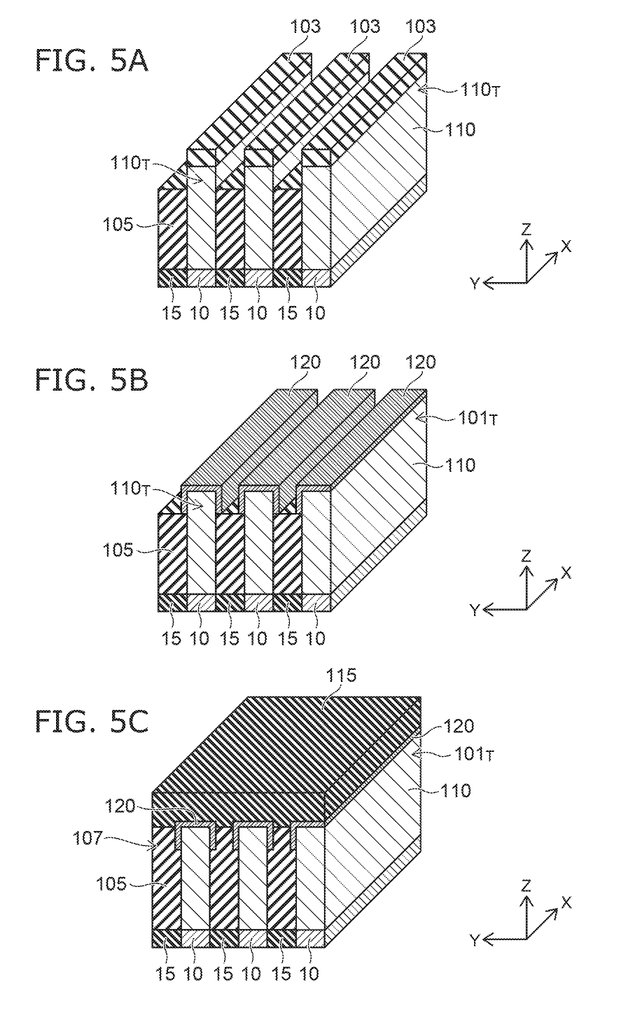

As shown in FIG. 5A, the insulating films 105 are selectively etched back so that the upper ends 110_{T} of the semiconductor layer 110 are higher than the upper surfaces of the insulating films 105. Subsequently, the mask layer 103 is selectively removed to expose the upper ends 110_{T} of the semiconductor layer 110.

As shown in FIG. 5B, semiconductor layers 120 are formed so as to cover the upper ends 110_{T} of the semiconductor layer 110. The semiconductor layers 120 are, for example, polycrystalline silicon layers deposited by a CVD process. Alternatively, the semiconductor layers 120 may be epitaxially grown silicon layers.

As shown in FIG. 5C, insulating films 107 are embedded on the insulating film 105 in the slits ST1 (see FIG. 4B), and further, a mask layer 115 is formed so as to cover the semiconductor layers 120 and the insulating films 107. The insulating films 107 are, for example, silicon oxide films, and the mask layer 115 includes, for example, silicon nitride deposited by a CVD process.

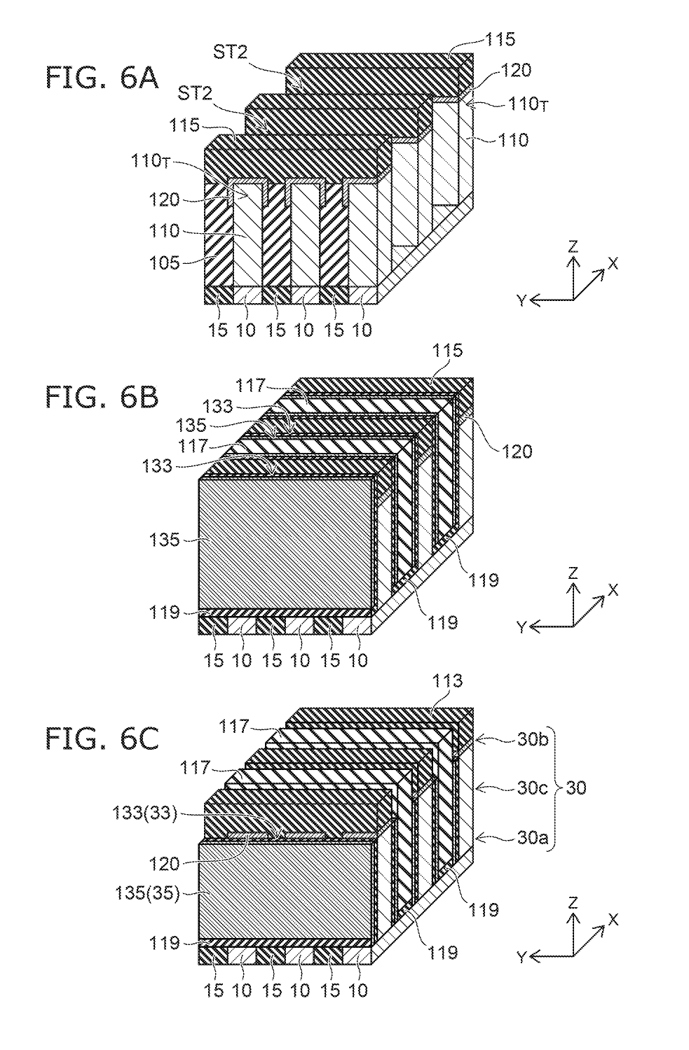

As shown in FIG. 6A, slits ST2 extending in the Y-direction are formed to divide the insulating films 105 and the semiconductor layer 110. The slits ST2 are formed, for example, by an anisotropic RIE process in which the semiconductor layer 110 and the insulating films 105 are selectively removed after the mask layer 115 is formed into a predetermined pattern by photolithography. Thereby, the semiconductor layer 110 is formed into parts with a rectangle columnar shape.

For example, each part of the semiconductor layer 110 formed into the rectangle columnar shape by an anisotropic RIE process has a tapered shape in which the widths in the X-direction and the Y-direction of the bottom part located on the interconnection 10 are wider than the widths of the upper end in the respective directions. In the embodiment, in order to widen the width in the Y-direction of the upper end of the semiconductor pillar 30 (see FIG. 1B), the semiconductor layers 120 are formed to cover the upper ends 110_{T} of the semiconductor layer 110.

As shown in FIG. 6B, insulating films 117 are formed in the slits ST2 after insulating films 133 and metal films 135 are formed to cover the side surfaces of the insulating films 105 and the semiconductor layer 110 exposed on the inner walls of the slits ST2. The insulating films 133 and the insulating films 117 are, for example, silicon oxide films. Each insulating film 133 can include silicon oxynitride. An easily processed material such as titanium nitride, tantalum nitride, or tungsten is preferably used for the metal films 135.

For example, after insulating films 119 are formed on the bottoms of the slits ST2, the insulating films 133 and the metal films 135 are sequentially formed to cover the inner surfaces of the slits ST2 and the upper surfaces of the mask layer 115. Subsequently, while leaving the parts of the insulating films 133 and the metal films 135 that cover the inner walls of the slits ST2, the other parts covering the bottom surfaces of the slits ST2 and the upper surfaces of the mask layers 115 are selectively removed, for example, by using an anisotropic RIE process. Then, the insulating films 117 are formed to fill the slits ST2. The insulating films 119 are spacer films provided for preventing the metal layers 135, which are the gate electrodes 35, from contacting the interconnection 10.

As shown in FIG. 6C, the insulating films 133 and the metal films 135 are selectively etched back to form the gate insulating films 33 and the gate electrodes 35 respectively. Thus, the semiconductor device 1 is completed.

### Second Embodiment

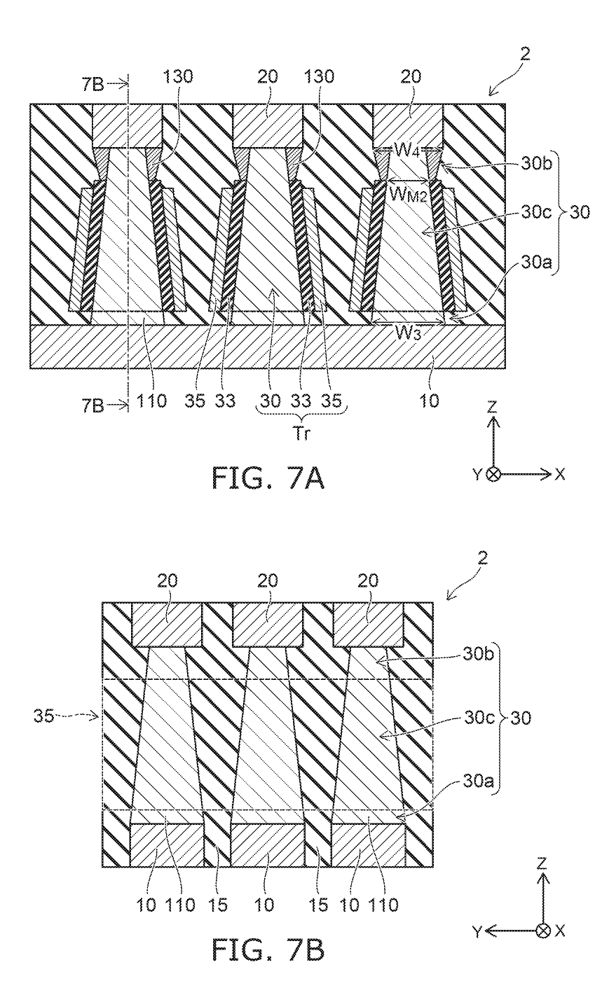

FIGS. 7A and 7B are schematic cross-sectional views showing a semiconductor device 2 according to a second embodiment. FIG. 7B is a cross-sectional view taken along a line 7B-7B shown in FIG. 7A. The semiconductor device 2 includes a plurality of transistors Tr provided on the interconnections 10, and the transistors Tr, for example, perform ON/OFF control of a current flowing between the interconnection 10 and the interconnection 20.

As shown in FIG. 7A, the transistors Tr each include the semiconductor pillar 30, the gate insulating film 33, and the gate electrode 35. The semiconductor pillar 30 includes the semiconductor layer 110 and semiconductor layers 130. The semiconductor layer 110 is provided so as to have contact with the interconnection 10 at the bottom surface of the semiconductor layer 110, and have contact with the interconnection 20 at the upper surface of the semiconductor layer 110. The semiconductor layer 110 has a tapered shape in which the width of the bottom surface having contact with the interconnection 10 is wider than the width of the upper surface having contact with the interconnection 20. The semiconductor layers 130 are provided on side surfaces of the upper ends 110_{T} of the semiconductor layers 110. Thus, the width W₄ of the second region 30b in the X-direction becomes wider than the minimum width W_{M2} of the intermediate region 30c in the X-direction. Moreover, the width W₃ of the first region 30a in the X-direction is wider than the minimum width W_{M2} of the intermediate region 30c in the X-direction.

As shown in FIG. 7B, the semiconductor layers 130 are not provided on the upper part of the semiconductor layer 110 in the Y-Z cross-section perpendicular to the X-direction. Accordingly, in the Y-Z cross-section, the width of the first region 30a in the Y-direction becomes wider than the minimum width of the intermediate region 30c in the Y-direction, but the width of the second region 30b in the Y-direction is narrower than the minimum width of the intermediate region 30c in the Y-direction.

In the embodiment, by making the width W₄ of the second region 30b in the X-direction wider than the minimum width W_{M2} of the intermediate region 30c in the X-direction, it is possible to suppress the reduction of the drain current Id, and to improve the reliability of the semiconductor device 2.

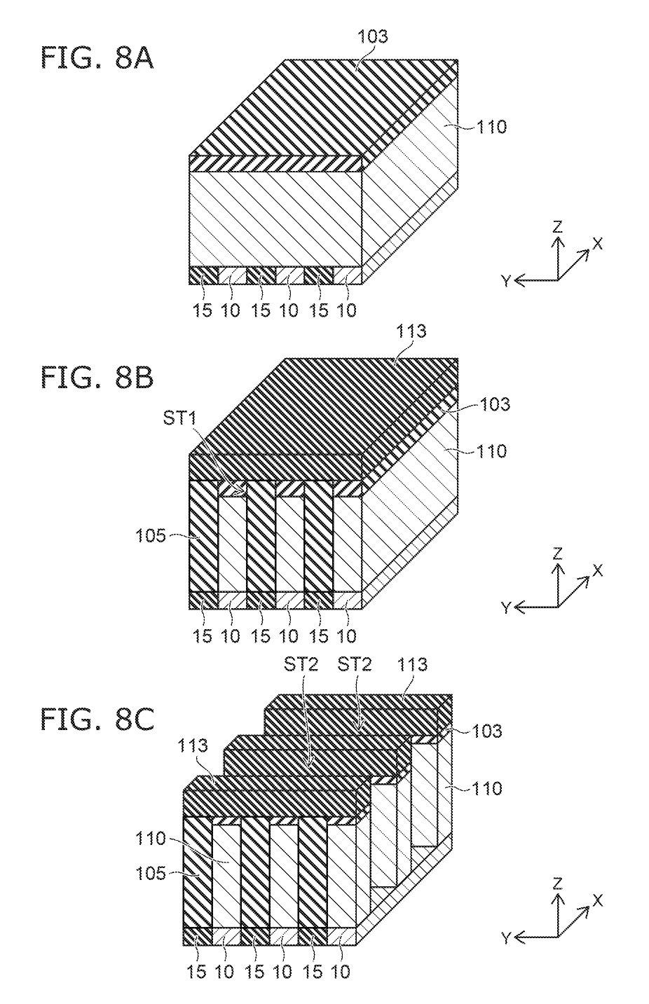

Then, a method of manufacturing the semiconductor device 2 according to the second embodiment will be described with reference to FIGS. 8A to 10B. FIGS. 8A to 10B are perspective views schematically showing the manufacturing process of the semiconductor device 2.

FIG. 8A is a perspective view showing the interconnections 10, a semiconductor layer 110 formed on the interconnections 10 arranged in the Y-direction, and the mask layer 103. The interconnections 10 extend in the X-direction, and are arranged in the Y-direction via the insulating films 15.

As shown in FIG. 8B, the insulating films 105 are formed in the slits ST1 dividing the mask layer 103 and the semiconductor layer 110 into a plurality of parts. It should be noted that the semiconductor layer 110 shown in FIGS. 7A and 7B corresponds to a part of the semiconductor layer 110 in FIG. 8A.

Then, the mask layer 113 is formed to cover the upper surfaces of the insulating films 105 and the upper surface of the mask layer 103. The slits ST1 are formed, for example, by selectively removing the semiconductor layer 110 by using the patterned mask layer 103. The semiconductor layer 110 is selectively removed by, for example, an anisotropic RIE process. The insulating films 105 are, for example, silicon oxide films deposited by a CVD process, and the mask layer 113 is, for example, a silicon nitride layer deposited by a CVD process.

As shown in FIG. 8C, the slits ST2 are formed for dividing the semiconductor layer 110 into parts that have a rectangle columnar shape. The slits ST2 are formed by, for example, an anisotropic RIE process in which the mask layer 103, insulating films 105 and the semiconductor layer 110 is selectively removed after the mask layer 113 is formed into a predetermined pattern by, for example, photolithography.

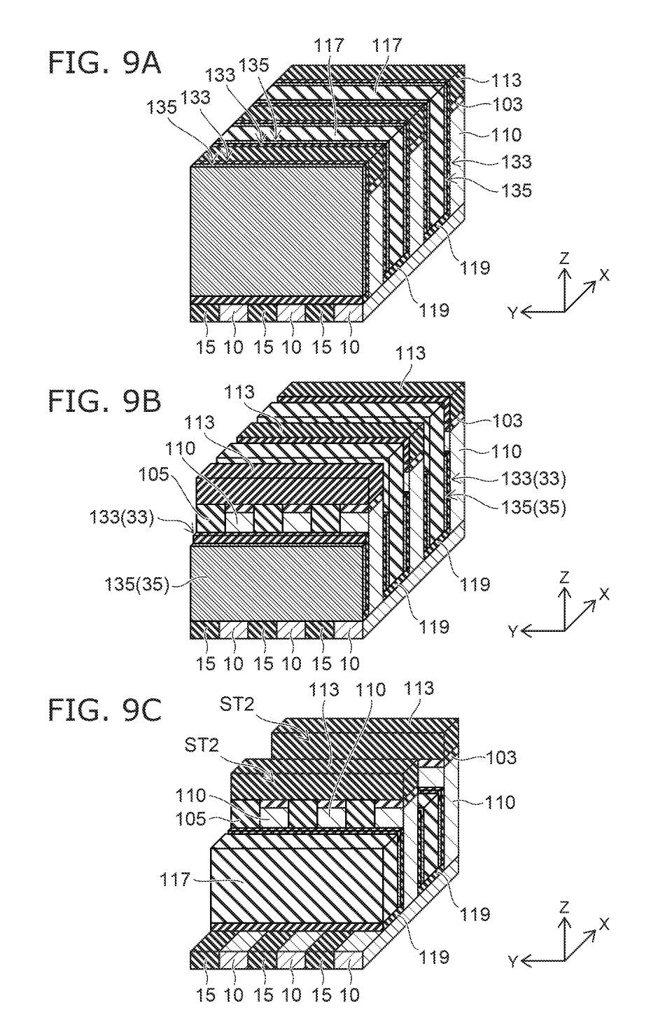

As shown in FIG. 9A, insulating films 117, 119, and 133, and the metal films 135 are formed in the slits ST2. The insulating films 119 are provided in the bottom parts of the slits ST2. The insulating films 133 and the metal films 135 are formed so as to cover the side surfaces of the semiconductor layer 110 and the insulating films 105 exposed on the inner walls of the slits ST2. The insulating films 117 are formed so as to fill the slits ST2.

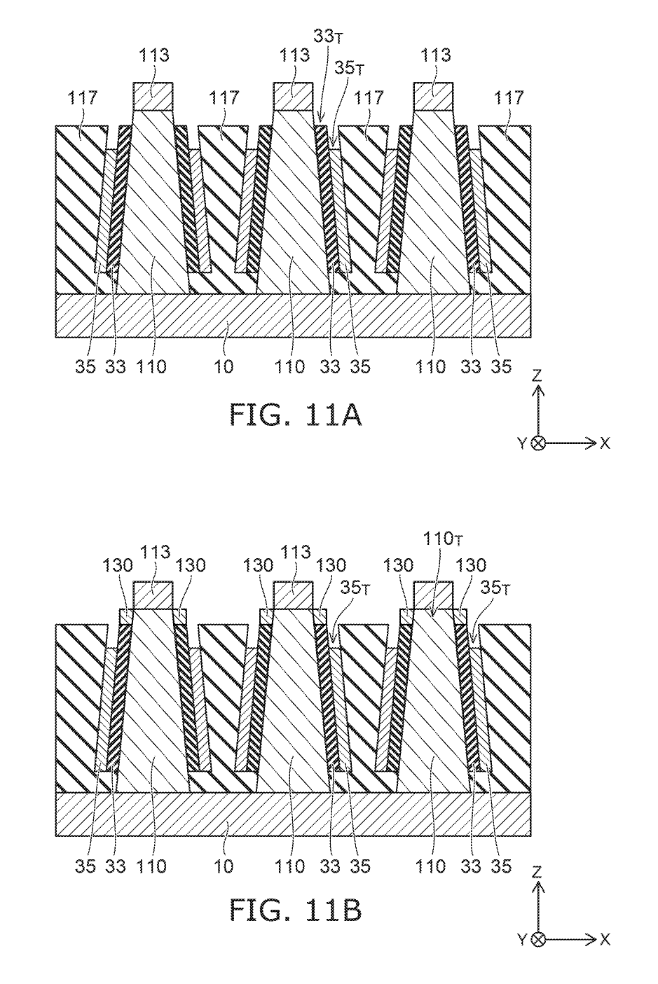

As shown in FIG. 9B, the insulating films 133 and the metal films 135 are selectively etched back to form the gate insulating films 33 and the gate electrodes 35. The insulating films 133 and the metal films 135 are partially removed, for example, to expose the upper ends 110_{T} of the semiconductor layer 110. In this case, the upper ends of the metal films 135 are preferably located at a level lower than the upper ends of the insulating films 133, or at a level same as the upper ends of the insulating films 133 (see FIGS. 11A and 11B).

As shown in FIG. 9C, the insulating films 117 are etched back to expose the upper ends 110_{T} of the semiconductor layer 110 on the upper parts of the slits ST2. In FIG. 9C, it should be noted that omitted is a part located on the front side of an insulating film 117 shown in front.

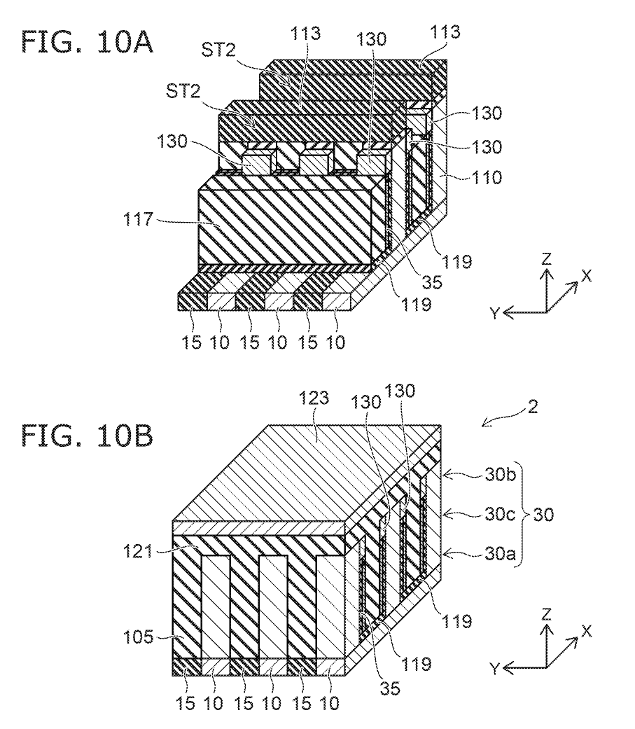

As shown in FIG. 10A, the semiconductor layers 130 are formed on the upper ends 110_{T} of the semiconductor layer 110 exposed on the inner walls of the slits ST2. The semiconductor layers 130 are, for example, polycrystalline silicon layers deposited by a CVD process. Alternatively, the semiconductor layers 130 may be epitaxially grown silicon layers.

As shown in FIG. 10B, an insulating film 121 is formed so as to be embedded in the upper parts of the slits ST2, and further, an insulating film 123 is formed on the insulating film 121. The insulating film 121 is, for example, a silicon oxide film, and the insulating film 123 is, for example, a silicon nitride film. Thus, the semiconductor device 2 is completed.

It should be noted that it is also possible in the process shown in FIG. 10A to form the semiconductor layers 130 after removing the insulating films 103 and 113 to expose the upper ends 110_{T} of the semiconductor layer 110. Thereby, the semiconductor layers 130 are formed to cover the upper surfaces of the semiconductor layer 110 and the two side surfaces in the X-direction of each upper end 110_{T}.

FIGS. 11A and 11B are perspective views schematically showing a part of the manufacturing process of the semiconductor device 2. FIG. 11A is a schematic view showing an X-Z cross-section in the process shown in FIG. 9B, and FIG. 11B is a schematic view showing an X-Z cross-section in the process shown in FIG. 10A.

As shown in FIG. 11A, the metal films 135 are preferably etched back to a level deeper than the insulating films 133 (see FIG. 9B). Thus, the upper ends 35_{T} of the gate electrodes 35 are provided so as to be positioned at a level lower than the upper ends 33_{T} of the gate insulating films 33.

As shown in FIG. 11B, when the semiconductor layers 130 are formed on the side surfaces of the upper ends 110_{T} of the semiconductor layer 110, the upper ends 35_{T} of the gate electrodes 35 are positioned below the semiconductor layers 130. Thus, it is possible to prevent the gate electrodes 35 and the semiconductor layers 130 from making short circuit.

### Third Embodiment

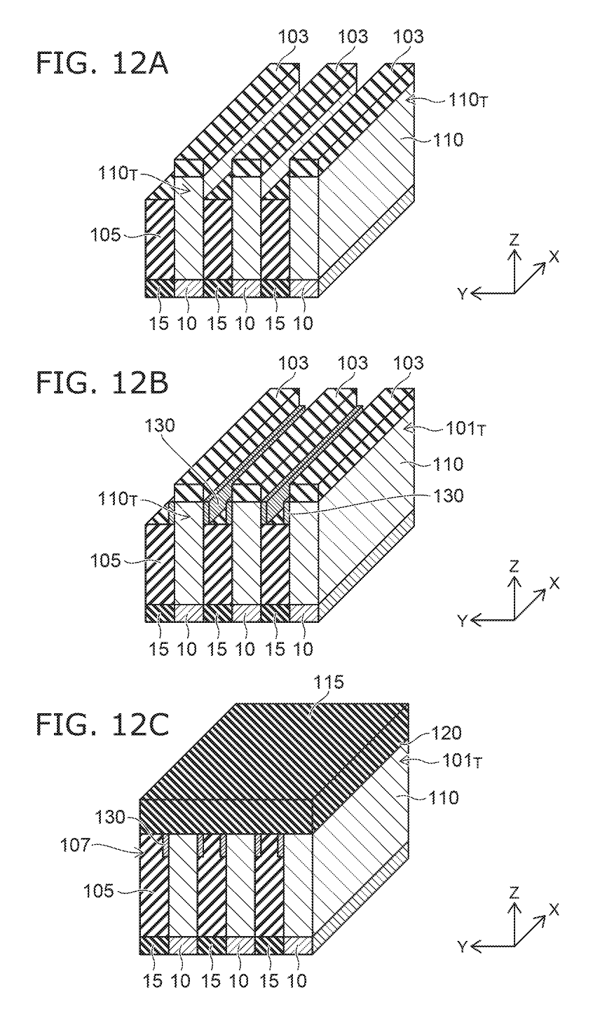

FIGS. 12A to 12C are perspective views schematically showing a method of manufacturing the semiconductor device 1 according to a third embodiment. FIG. 12A is a perspective view same as one shown in FIG. 5A. That is, the semiconductor device 1 is formed through the manufacturing process same as that of the semiconductor device 1 before the step shown in FIG. 5A.

As shown in FIG. 12B, the semiconductor layers 130 are formed on the side surfaces of the upper ends 110_{T} of the semiconductor layer 110, which are exposed by etching back the insulating films 105. The semiconductor layers 130 are, for example, polycrystalline silicon layers formed by a CVD process, or epitaxially grown silicon layers.

As shown in FIG. 12C, the insulating film 115 is formed on the surface planarized by CMP (Chemical Mechanical Polishing) which is performed after removing the insulating films 103 and filling the upper portions of the slits ST1 with the insulating films 107 provided on the insulating films 105. Subsequently, the process shown in FIGS. 6A to 6C is performed, and thus, the semiconductor device 1 is completed.

### Fourth Embodiment

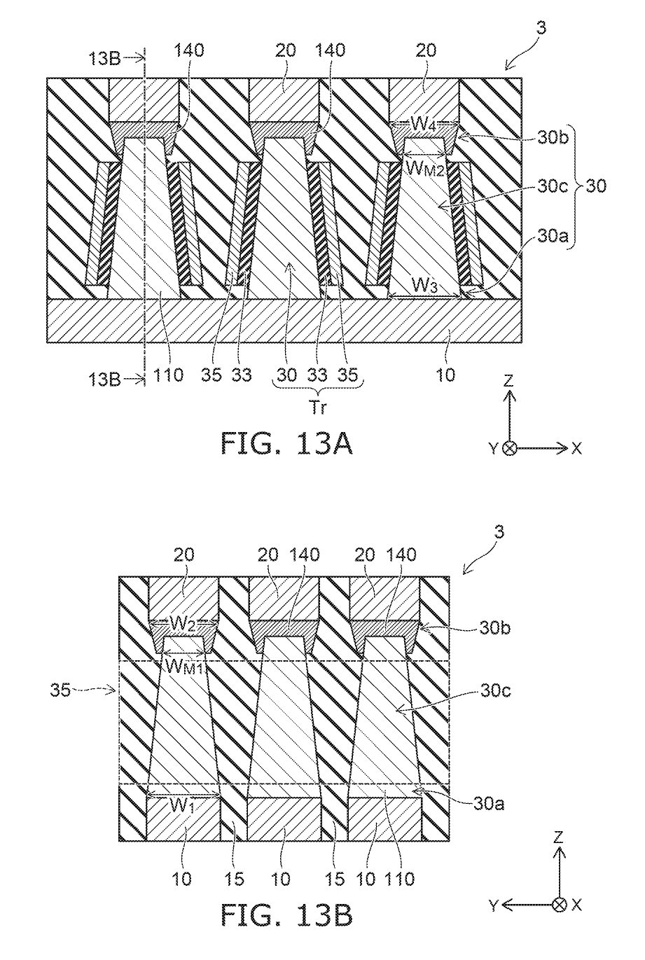

FIGS. 13A and 13B are schematic cross-sectional views showing a semiconductor device 3 according to a fourth embodiment. FIG. 13B is a cross-sectional view taken along a line 13B-13B shown in FIG. 13A. The semiconductor device 3 includes a plurality of transistors Tr provided on the interconnections 10, and each transistor Tr, for example, performs ON/OFF control of a current flowing between the interconnection 10 and the interconnection 20.

As shown in FIG. 13A, each transistor Tr includes the semiconductor pillar 30, the gate insulating film 33, and the gate electrode 35. The semiconductor pillar 30 includes a semiconductor layer 110 and a semiconductor layer 140. The semiconductor layer 110 is in contact with the interconnection 10 at the bottom surface of the semiconductor layer 110. The semiconductor layer 140 is provided so as to cover the upper end of the semiconductor layer 110, and is in contact with the interconnection 20 at the upper surface of the semiconductor layer 140. The semiconductor layer 110 is provided to have a tapered shape in which the width of the bottom surface that is in contact with the interconnection 10 is wider than the width of the upper end of the semiconductor layer 110. Accordingly, the width W₃ of the first region 30a in the X-direction becomes wider than the minimum width W_{M2} of the intermediate region 30c in the X-direction, and the width W₄ of the second region 30b in the X-direction also becomes wider than the width W_{M2} of the intermediate region 30c in the X-direction.

As shown in FIG. 13B, in the Y-Z cross-section perpendicular to the X-direction, the semiconductor layer 140 also covers the upper end of the semiconductor layer 110. Therefore, in the Y-Z cross-section, the width W₁ of the first region 30a in the Y-direction also becomes wider than the minimum width W_{M1} of the intermediate region 30c in the Y-direction, and the width W₂ of the second region 30b in the Y-direction becomes wider than the minimum width W_{M1} of the intermediate region 30c in the Y-direction. Thus, in the semiconductor device 3, it is possible to suppress the reduction of the drain current Id, and to improve the reliability.

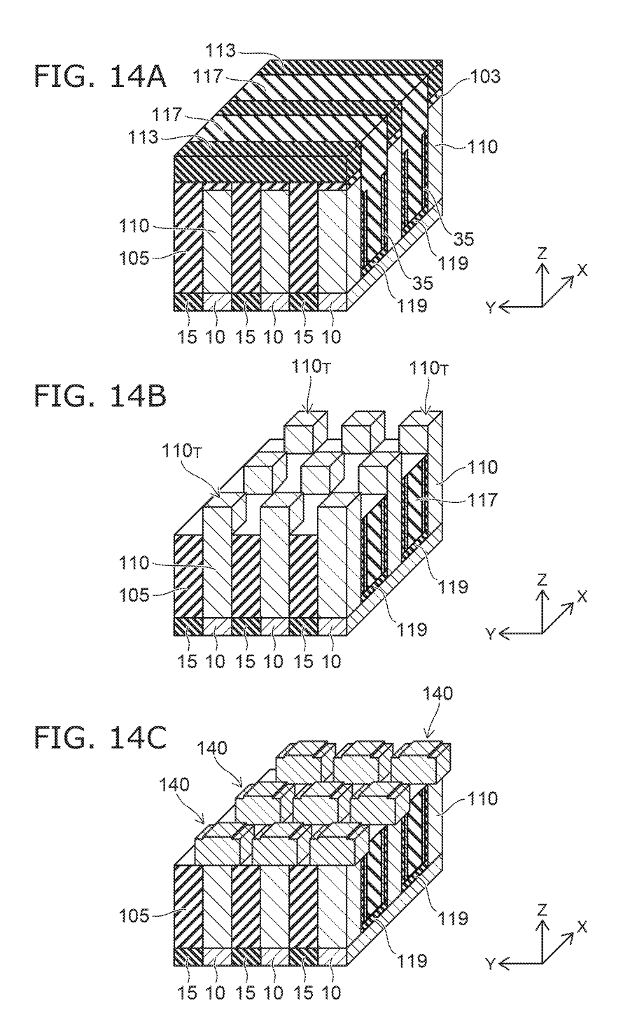

Then, a method of manufacturing the semiconductor device 3 according to the fourth embodiment will be described with reference to FIGS. 14A to 14C. FIGS. 14A to 14C are perspective views schematically showing the manufacturing process of the semiconductor device 3. FIGS. 14A to 14C are perspective views showing a manufacturing process to be performed after forming the gate insulating films 33 and the gate electrodes 35 by etching back the insulating films 133 and the metal films 135 in the step shown in FIG. 9B.

As shown in FIG. 14A, the gate electrodes 35 are formed in the slits ST2 so as to face the side surfaces of the semiconductor layer 110 via the insulating films 33. Further, the insulating films 117 and 119 are formed to fill the slits ST2. The insulating films 119 are provided at the bottoms of the slits ST2.

As shown in FIG. 14B, the upper ends 110_{T} of the semiconductor layer 110 are exposed. It should be noted that the semiconductor layers 110 shown in FIGS. 13A and 13B correspond to parts of the semiconductor layer 110 in FIG. 14.

For example, the insulating films 117 are etched back so that the upper surfaces of the insulating films 117 are positioned at a level substantially same as the upper surfaces of the mask layers 103. Subsequently, the mask layers 103 and 113 are selectively removed to expose the upper surfaces of the semiconductor layers 110. Further, the insulating films 105 and 117 are etched back to expose the upper ends 110_{T} of the semiconductor layer 110. In this case, the upper surfaces of the insulating films 105 and 117 are preferably positioned at a level higher than the upper ends of the gate electrodes 35.

As shown in FIG. 14C, the semiconductor layers 140 are formed to cover the upper ends 110_{T} of the semiconductor layer 110. The semiconductor layers 140 are, for example, polycrystalline silicon layers deposited by a CVD process. Alternatively, the semiconductor layers 140 may be epitaxially grown silicon layers. Subsequently, an insulating film covering the semiconductor layers 140 is formed to complete the semiconductor device 3.

### Fifth Embodiment

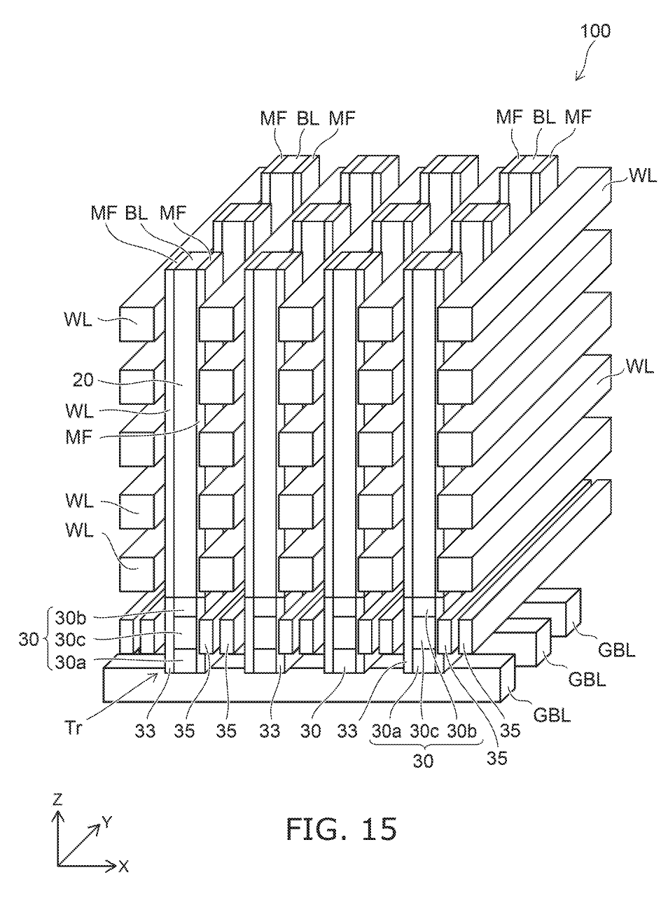

FIG. 15 is a perspective view schematically showing a storage device 100 according to a fifth embodiment. As shown in FIG. 15, the storage device 100 includes a plurality of global bit lines GBL extending in the X-direction and arranged in the Y-direction, and a plurality of transistors Tr disposed on the respective global bit lines GBL.

The transistors Tr each include the semiconductor pillar 30, the gate insulating film 33, and the gate electrode 35. The semiconductor pillar 30 includes the first region 30a, the second region 30b and the intermediate region 30c, and the first region 30a is connected to a global bit line GBL. The gate electrode 35 extends in the Y-direction, and faces the intermediate region 30c via the gate insulating film 33.

The storage device 100 further includes bit lines BL, word lines WL, and memory film MF. The bit lines BL extend in the Z-direction, and each bit line BL is connected to the second region 30b of the transistor Tr at the lower end thereof. The transistor Tr, for example, performs ON/OFF control of the current flowing between the global bit line GBL and a bit line BL. The word lines WL extend in the Y-direction, and are stacked in the Z-direction along the bit lines BL. The memory film MF is positioned between the bit line BL and a word line WL, and include a variable resistance material.

For example, by defining the interconnections 10 as the global bit lines GBL, and the interconnections 20 as the bit lines BL, either one of the semiconductor devices 1 to 3 constitutes a part of the storage device 100. Thus, the reliability of the storage device 100 can be improved.

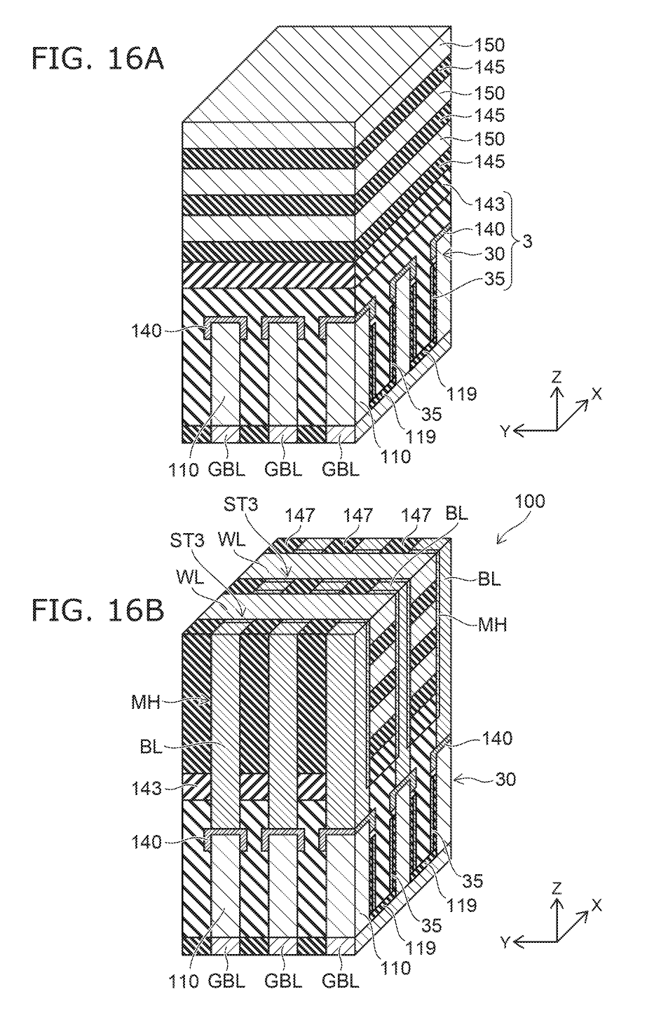

FIGS. 16A and 16B are perspective views schematically showing a manufacturing process of the storage device 100 according to the fifth embodiment. In this example, the interconnections 10 of the semiconductor device 3 are replaced with the global bit lines GBL.

As shown in FIG. 16A, for example, insulating films 143, 145 and conductive layers 150 are stacked on the semiconductor device 3. The insulating film 143 is, for example, a silicon nitride film, and the insulating films 145 are, for example, silicon oxide films. The conductive layers 150 are, for example, low-resistance polycrystalline silicon layers or metal layers. The insulating films 145 and the conductive layers 150 are alternately stacked on the insulating film 143.

As shown in FIG. 16B, slits ST3 are formed for dividing the insulating films 145 and the electrically conductive layer 150, and then, the word lines WL are formed to extend in the Y-direction. Each word line WL is a part of the conductive layers 150 divided by the slits ST3.

Subsequently, the memory films MF and the bit lines BL are formed in the slits ST3. For example, the memory films MF are formed in the slits ST3, and then, insulating films 147 are embedded in the slits ST3. Further, the insulating films 147 are selectively removed to form memory holes MH each communicated with the semiconductor pillar 30 from the upper surface of the insulating film 147. Subsequently, metal films are embedded in the memory holes MH to form the bit lines BL. Thus, the storage device 100 is completed.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device comprising:
a semiconductor pillar extending in a first direction, and including a first region, a second region and an intermediate region provided along the first direction, the intermediate region being positioned between the first region and the second region; and
a control electrode disposed at a position so that the control electrode faces the intermediate region via an insulating film,
the semiconductor pillar being provided so that a minimum width of the intermediate region in a second direction perpendicular to the first direction is narrower than a first width of the first region in the second direction and a second width of the second region in the second direction.

2. The device according to claim 1, wherein the first width is wider than the second width.

3. The device according to claim 1, wherein the first width is substantially the same as the second width.

4. The device according to claim 1, wherein the first width is narrower than the second width.

5. The device according to claim 1, further comprising:
a first interconnection extending in a third direction perpendicular to the first direction and crossing the second direction, and connected to the first region.

6. The device according to claim 5, wherein the control electrode extends in the second direction.

7. The device according to claim 5, wherein
a minimum width of the intermediate region in the third direction is narrower than a third width of the first region in the third direction and a fourth width of the second region in the third direction.

8. The device according to claim 1, further comprising:
a first interconnection connected to the first region and extending in the second direction,
wherein the control electrode extends in a third direction perpendicular to the first direction and crossing the second direction.

9. The device according to claim 1, wherein
the first region, the second region and the intermediate region include impurities of same conductivity types, and
the impurities included in the first region and the second region are higher in concentration than the impurities included in the intermediate region.

10. The device according to claim 1, wherein
the semiconductor pillar has a tapered shape such that a width of the semiconductor pillar in a third direction perpendicular to the first direction and crossing the second direction becomes narrower in the first direction.

11. The device according to claim 1, wherein
the semiconductor pillar includes a silicon pillar and a silicon layer selectively grown on an upper part of the silicon pillar.

12. The device according to claim 11, wherein
the silicon pillar has a tapered shape having a width in the second direction narrowing in the first direction.

13. The device according to claim 11, wherein
the silicon layer is provided on a side surface of the upper part of the silicon pillar.

14. The device according to claim 11, wherein
the silicon layer covers an upper surface and a side surface of the upper part of the silicon pillar.

15. The device according to claim 5, further comprising:
a second interconnection connected to the second region and extending in the first direction,
wherein the intermediate region has the minimum width at a boundary with the second region,
the first region has the first width at a boundary with the first interconnection, and
the second region has the second width at a boundary with the second interconnection.

16. The device according to claim 5, further comprising:
a second interconnection connected to the second region and extending in the first direction;
a third interconnection extending in the second direction and crossing the second interconnection; and
a variable resistance film provided between the second interconnection and the third interconnection.
